(19) United States
(12) Patent Application Publication
(10) Pub. No.: US 2007/0190362 A1
(43) Pub. Date: Aug. 16, 2007

(54) PATTERNED ELECTROLESS METALLIZATION PROCESSES FOR LARGE AREA ELECTRONICS

(76) Inventor: Timothy W. WEIDMAN, Sunnyvale, CA (US)

Correspondence Address: PATTERSON & SHERIDAN, LLP, 3040 POST OAK BOULEVARD, SUITE 1500, HOUSTON, TX, 77056, US

(21) Appl. No.: 11/530,003

(22) Filed: Sep. 7, 2006

Related U.S. Application Data
(60) Provisional application No. 60/715,024, filed on Sep. 8, 2005.

(51) Int. Cl. B05D 5/12; C23C 16/00; B05D 3/00; B05D 7/00; B32B 9/00

(52) U.S. Cl. 428/701; 427/124; 427/299; 427/402; 427/248.1; 428/702

(57) ABSTRACT

The present invention generally provides an apparatus and method for selectively forming a metallized feature, such as an electrical interconnect feature, on a electrically insulating surface of a substrate. The present invention also provides a method of forming a mechanically robust, adherent, oxidation resistant conductive layer selectively over either a defined pattern or as a conformal blanket film. Embodiments of the invention also generally provide a new chemistry, process, and apparatus to provide discrete or blanket electrochemically or electrolessly platable ruthenium or ruthenium dioxide containing adhesion and initiation layers. In general, aspects of the present invention can be used for flat panel display processing, semiconductor processing, solar cell device processing, or any other substrate processing, being particularly well suited for the application of stable adherent coating on glass as well as flexible plastic substrates. This invention may be especially useful for the formation of electrical interconnects on the surface of flat panel display or solar cell type substrates where the line sizes are generally larger than semiconductor devices or where the formed feature are not generally as dense.

### CROSS-REFERENCE TO RELATED APPLICATIONS

This application claims the benefit of the U.S. Provisional Patent Application Ser. No. 60/715,024, filed Sep. 8, 2005, which is herein incorporated by reference.

### BACKGROUND OF THE INVENTION

1. Field of the Invention

Embodiments of the invention generally relate to methods for depositing a catalytic layer on a surface of a substrate, prior to depositing a conductive layer thereon.

2. Description of the Related Art

Metallization of flat panel display devices, solar cells, and other electronic devices using conventional techniques, such as electroless plating and electrochemical plating have some negative characteristics, which often include poor adhesion to the substrate surface. Therefore, during the formation of interconnecting layer, such as a copper layer over films deposited using conventional techniques, the intrinsic or extrinsic stress of the deposited layers often lead to debonding of the metal layers from the surface of the substrate.

Also, conventional deposition technologies, such as physical vapor deposition (PVD) and electrochemical metallization processes cannot be used to selectively form metallized features on the surface of a substrate. To form discrete features using non-selective deposition processes will require the steps of lithographic patterning and metal etch steps to achieve the desired conductive pattern on the substrate surface, which are often cost prohibitive, time intensive, and/or labor intensive.

In the solar cell, laptop computer, flat panel display and structural glass and other similar applications that may be exposed to atmospheric and other contaminants that will corrode the base material (e.g., metals, glass, printed circuit board layers) or conductive traces formed on the surface of a substrate. In a number of applications it is desirable to form a blanket coating or discrete conductive regions that can pass an applied current or are static dissipative without significant attack.

Therefore, a need exists for a method to directly deposit a conductive metal layer in a desired pattern to form interconnect features or other device structures that exhibits strong adhesion to the substrate surface.

### SUMMARY OF THE INVENTION

The present invention generally provides a method of forming a conductive feature on the surface of a substrate, comprising depositing a coupling agent that contains a metal oxide precursor on a surface of a substrate; and exposing the coupling agent and the surface of the substrate to a ruthenium tetroxide containing gas to form a ruthenium containing layer on the surface of the substrate.

Embodiments of the invention further provide a method of forming a conductive feature on the surface of a substrate, comprising depositing an organic containing material on a surface of a substrate, exposing the organic material and the surface of the substrate to a ruthenium tetroxide containing gas, wherein the ruthenium tetroxide oxidizes the organic material to selectively deposit a ruthenium containing layer on the surface of the substrate, and depositing a conductive layer on the ruthenium containing layer using an electroless deposition process.

Embodiments of the invention further provide a method of forming a conductive feature on the surface of a substrate, comprising depositing a liquid coupling agent that contains a metal oxide precursor on a surface of a substrate, reducing the metal oxide precursor using a reducing agent, and depositing a conductive layer on the ruthenium containing layer using an electroless deposition process.

Embodiments of the invention further provide a method of selectively forming a layer on a surface of a substrate, comprising selectively applying a liquid coupling agent to a desired region on the surface of a substrate, and forming a ruthenium containing layer within the desired region using a ruthenium tetroxide containing gas.

Embodiments of the invention further provide a layered metal oxide coating formed on a substrate, comprising a ruthenium containing coating formed by the decomposition of ruthenium tetroxide, and a metal oxide coating formed by the decomposition of a vapor phase metal containing precursor.

Embodiments of the invention further provide a conductive coating formed on a substrate, comprising a mixed metal oxide coating deposited on a surface of the substrate by delivering a ruthenium tetroxide containing gas and a volatile metal oxide containing precursor to a surface of a substrate.

Embodiments of the invention further provide a method of forming a conductive feature on the surface of a substrate, comprising forming a dielectric layer between two discrete devices formed on a substrate surface by depositing a polymeric material on the surface of the substrate, exposing the dielectric layer to a ruthenium tetroxide containing gas, wherein the ruthenium tetroxide oxidizes the surface of the dielectric layer to form a ruthenium containing layer, and depositing a conductive layer on the ruthenium containing layer using an electroless deposition process.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is an isometric view which illustrates a substrate that has metallized features formed thereon;

FIG. 2 illustrates another process sequence according to one embodiment described herein;

FIGS. 3A-C is a cross-sectional view of the surface of the substrate that illustrate the bonding of various components to the surface of the substrate during different phases of the method steps 100;

FIG. 4 illustrates another process sequence according to one embodiment described herein;

FIG. 5 illustrates a schematic cross-sectional view of a process chamber that may be adapted to perform an embodiment described herein.

FIG. 6 illustrates another process sequence according to one embodiment described herein;

FIG. 7A illustrates another process sequence according to one embodiment described herein;

FIG. 7B illustrates another process sequence according to one embodiment described herein;

FIG. 7C illustrates a cross-sectional view of a process vessel that may be adapted to perform an embodiment described herein.

FIGS. 8A-C illustrate a schematic cross-sectional views of an integrated circuit fabrication sequence formed by a process described herein.

FIG. 9 illustrates a process sequence according to one embodiment described herein.

### DETAILED DESCRIPTION

The present invention generally provides an apparatus and method for selectively forming a metallized feature, such as an electrical interconnect feature, on a electrically insulating surface of a substrate. In general, aspects of the present invention can be used for flat panel display processing, semiconductor processing, solar cell processing, or any other substrate processing. This invention may be especially useful for the formation of electrical interconnects on the surface of large area substrates where the line sizes are generally larger than semiconductor devices (e.g., nanometer range) and/or where the formed feature are not generally as dense. Other features of the invention make it advantageous as a means to apply robust, adherent blanket conductive layers (or precursors to conductive layers) over an entire substrate, as is particularly the case when it is desired to coat complex three dimensional topographies with a uniform conformal coating. The invention is illustratively described below in reference to a chemical vapor deposition system, for processing large area substrates, such as a CVD system, available from AKT, a division of Applied Materials, Inc., Santa Clara, Calif. In one embodiment, the processing chamber is adapted to process substrates that have a surface area of at least about 2000 cm². However, it should be understood that the apparatus and method have utility in other system configurations, including those systems configured to process round or three dimensional substrates enclosed within a vacuum processing chamber or other vessel permitting the introduction of vapor phase reactants in a controlled fashion.

The present invention also generally provides a method of forming a conductive layer that can be selectively applied to a surface of a substrate or deposited as a blanket film that exhibits good corrosion resistance so that it can be used in aggressive environments without significant degradation of the deposited layer. The deposited conductive layer may exhibit partial transparency across the visible spectrum, good oxidization resistance, and dimensional stability. Films of this type may be useful in applications, such as an anode in an electrochemical device. Embodiments of the invention also generally provide a new chemistry, process, and apparatus to provide conformal and direct electrochemically or electrolessly platable ruthenium (Ru) or ruthenium dioxide (RuO₂) containing layers. The methods described herein generally avoid many of the cost, conformality, and lack of selectivity associated with other conventional methods. The reactive nature of the proposed chemistry provides physical vapor deposition (PVD) like adhesion with atomic layer deposition (ALD) like conformality and uniformity. Since the temperature requirements for the deposition step are generally less than 100° C., both the process and subsequent electroless plating steps are well suited for the coating of high temperature sensitive polymers and other organic materials. The catalytic properties of the deposited ruthenium containing layer provide a robust initiation layer for electroless metallization of virtually any dielectric, barrier or metal substrate.

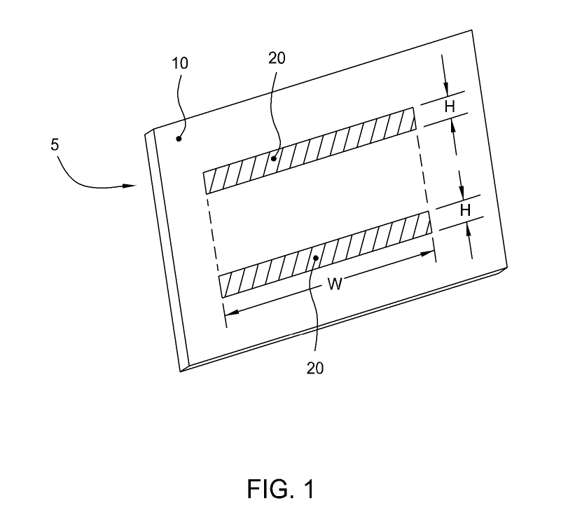

In general, the embodiments described herein are completed by following the various process sequences described below. FIG. 1 illustrates a substrate 5 that has two features 20 patterned on a surface 10 by use of one of the processes described below. In one embodiment, the surface 10 of the substrate 5 can be made from any number of electrically insulating, semiconducting, or conducting layers including silicon dioxide, glass, silicon nitride, oxynitride and/or carbon-doped silicon oxides, amorphous silicon, doped amorphous silicon, zinc oxide, indium tin oxide, or other similar material. In another embodiment, the substrate may have at least a portion of the exposed surface that contains an early transition metal, such as titanium or tantalum, which is prone to the formation of passivating or insulating oxide films over their surface. In yet another embodiment, the substrate may be formed from a polymer or plastic material that needs conductive metal features formed thereon.

Coupling Agent Approach

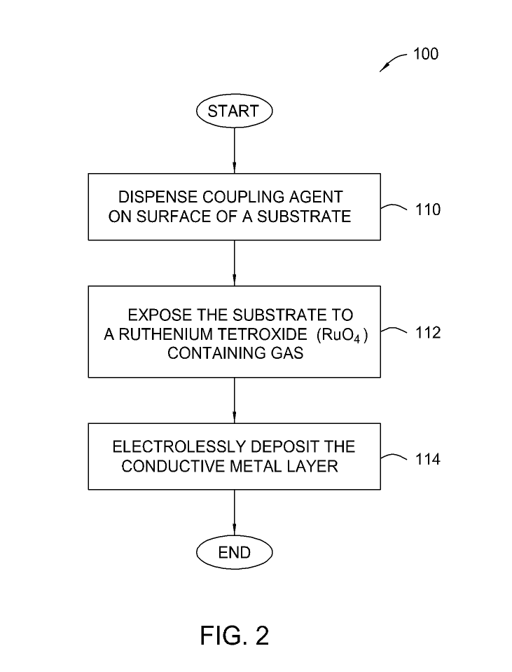

FIG. 2 illustrates one embodiment of a series of method steps 100 that may be used to form a conductive feature 20 (FIG. 1) on the surface of the substrate 5 using a coupling agent. In the first step, or the dispense coupling agent step 110, a coupling agent is dispensed on the surface of the substrate to form a feature 20 of a desired shape and size. In one example, as shown in FIG. 1, two features 20 that are rectangular in shape and have dimensions that are “W” long and “H” high were deposited on the surface 10 of the substrate 5. The process of forming the features 20 may generally include, but are not limited to an inkjet printing technique, rubber stamping technique or other technique that may be used to dispense a solution to form a pattern on the surface of the substrate having a desired size and shape. An exemplary method and apparatus that may be used to deposit the coupling agent is described in the US Patent Publication No. 20060092204, which is incorporated by reference to the extent not inconsistent with the claimed aspects and description herein.

In one embodiment, the coupling agent can be any organic material (CₓH_{y}) that can be deposited in a well defined pattern without spreading across the substrate surface and which can be oxidized in a subsequent process step. For example, even conventional inks used in typical rubber stamp pads or inkjet printing inks may can be useful to form the features 20 on the surface 10 of many inorganic dielectrics and not readily oxidizable substrates, such as silicon dioxide or glass.

In another embodiment, an organosilane based coupling agent, including those capabable of generating a self-assembled-monolayer (SAM) films on an Si—OH terminated surface (e.g., aminopropyltriethoxysilane (APTES)) is used. In one embodiment, a SAM material is patterned on the surface 10 of the substrate (FIG. 1) by use of an inkjet, rubber stamping, or any technique for the pattern wise deposition (i.e., printing) of a liquid or colloidal media on the surface of a solid substrate. In one embodiment, this step is followed by a subsequent thermal post treatment or simply an amount of time sufficient to permit any solvent or excess coupling agent (i.e., a SAM precursor) to evaporate. In other embodiments, after a time or thermal treatment sufficient to achieve strong and selective bonding of a single monolayer to the substrate surface, excess material may be removed by rinsing with a suitable solvent and the pattern permitted to dry.

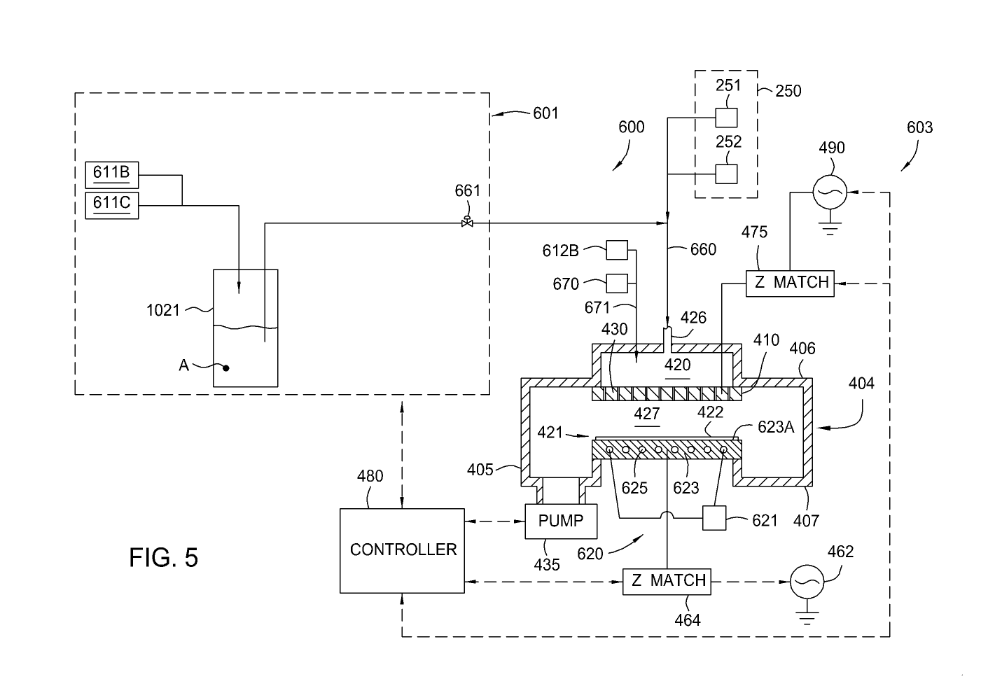

In the second step, or the expose substrate to a ruthenium tetroxide containing gas step 112, the substrate is positioned in a vacuum compatible processing chamber 603, discussed below in conjunction with FIG. 5, so that a ruthenium tetroxide containing gas can be delivered to the features 20 formed on the surface of the substrate 5. Since ruthenium tetroxide (Ru0₄) is such a strong oxidizing agent the coupling agent material deposited in step 110 is selectively replaced with a ruthenium containing layer (e.g., RuO₂), which will exhibit catalytic activity towards the growth of a subsequent metal film deposited by an electroless plating technique.

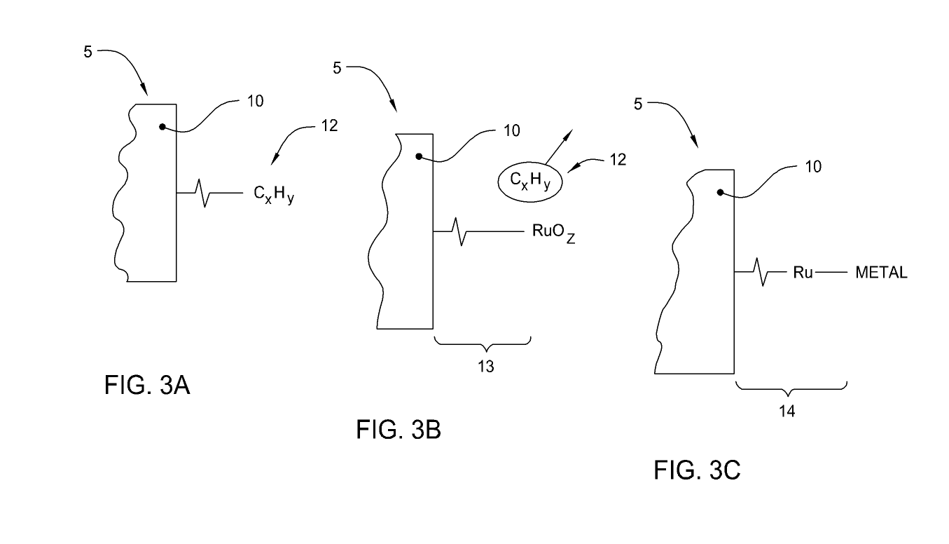

FIGS. 3A-B schematically illustrate one embodiment of the process steps 110-112 illustrated in FIG. 2, respectively. FIG. 3A schematically illustrates a bonded coupling agent molecule 12 that is attached to the surface 10 on the substrate 5. The coupling agent molecule 12 illustrated in FIG. 3A is intended to only pictorially show one of many molecules found in the features 20 formed on the surface of the substrate 5.

FIG. 3B illustrates the step 112 where due to the interaction of the coupling agent molecule 12 in feature 20 and a ruthenium tetroxide molecule (not shown), a ruthenium oxide (e.g., RuO₂) molecule substitutionally replaces the position of the coupling agent molecule 12 on the surface of the substrate. It should be noted that when a silane based coupling agent is used the silicon atoms will remain and the organic components of the SAM will be oxidized and replaced by the ruthenium oxide. In this case the silane based coupling agent will thus form a Si—O—RuOₓ type bond to the surface of the substrate. A unique feature associated with the use of a Ru0₄ based activation process is the ability to use virtually any organic and oxidizable material (including conventional inks) as the patterning media, and the fact that the organic material originally present is generally eliminated during the RuO₂ deposition process, thus facilitating the formation of a highly conductive layer and in certain cases ohmic contact to an underlying device layer, particularly when the latter is a conductive oxide or material rendered conductive in post ruthenium deposition steps. In another embodiment, a coupling agent such as APTES, is specifically used due to its ability to coordinate and create a bonding site for a catalytic agent, such as a palladium salt, which is brought into contact with the surface of the coupling agent found in the formed features 20. After the catalytic agent is bonded to the coupling agent then it is generally desirable to “fix” or “activate” the catalytic species by subsequent exposure to a reducing agent known to effect the reduction of the coordinated species to zero valent atomic metal nuclei, or nanoclusters, to facilitating subsequent catalysis of the electroless plating of a continuous conductive metal feature thereon using an autocatalytic electroless plating process.

In one aspect of the invention, in step 112 the ruthenium containing layer is reacted with the coupling agent material (deposited in step 110) in the vacuum chamber at a substrate temperature less than 180° C. and chamber pressure between about 10 mtorr and about one atmosphere (or about 760 Torr). In cases where the amount of readily oxidizable ink exceeds the RuO₄ made available to oxidize it, treatment (e.g., >150° C.) can result in the complete or partial reduction of initially generated RuO₃ to ruthenium metal. Exemplary processes used to form ruthenium tetroxide and perform step 112 are discussed below in the section entitled “Ruthenium Process Chemistry And Enabling Hardware” and is further described in the U.S. Provisional Patent Application Ser. No. 60/648,004 filed Jan. 27, 2005 and the commonly assigned U.S. patent application Ser. No. 11/228,425 [APPM 9906], filed Sep. 15, 2005, which are both incorporated by reference to the extent not inconsistent with the claimed aspects and description herein.

Referring to FIGS. 2, 3B-3C, in the final step, or step 114, an electroless plating process can be used to deposit a conductive layer on the catalytic Ru or Ru0₂ layer 13 formed in the step 112. In this step the features 20, which contains the catalytic Ru0₂ layer 13, are exposed to a electroless chemistry (e.g., conventional electroless copper (Cu) chemistry) causing the initiation of autocatalytic plating selectively over the ruthenium covered surface. Step 114 is generally used to form a metallic layer, or conductive layer 14, on the patterned catalytic ruthenium based adhesion and initiation layer that has properties (e.g., thickness and conductive properties) that allow the formed conductive layer 14 to pass a desired amount of current. In one aspect, the conductive layer 14, which contains the ruthenium and the electrolessly deposited metal, may be between about 20 angstroms (Å) and about 2 micrometers (μm) thick. In one aspect, the electrolessly deposited metal may contain a metal such as copper (Cu), nickel (Ni), ruthenium (Ru), cobalt (Co), silver (Ag), gold (Au), platinum (Pt), palladium (Pd), rhodium (Rh), Iridium (Ir), lead (Pb), tin (Sn) or other metals and alloys platable using an autocatalytic electroless process. Alternative, particularly in the case of a blanket Ru0₄ derived process or structure where patterned features may be electrically contacted, further metallization may be accomplished by electroplating as well

In one embodiment of the method steps 100, prior to forming the conductive layer in step 114 a brief (e.g., 2 minute) forming gas anneal to convert Ru0₂ surface to metallic ruthenium is performed on the substrate 5. In general the anneal process may be performed at a temperature between about 150° C. and about 500° C. This anneal may be useful to improve the initiation speed and adhesion of the conductive layer 14 grown during the electroless plating step 114.

Metal Oxide Precursor Based Inks and Adhesion Layers

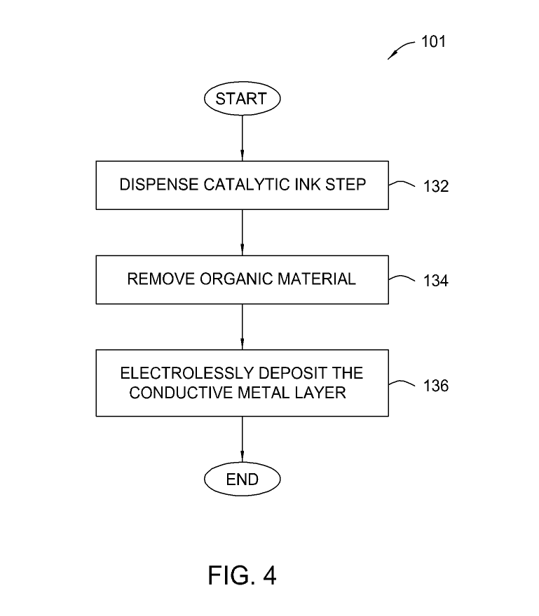

FIG. 4 Illustrates one embodiment of a series of method steps 101 that may be used to form the metallized feature on the surface of the substrate 5 using an ink or blanket coating containing a precursor to a metal oxide selected to bond strongly to both the substrate and RuO₂ generated in the subsequent vapor phase reaction with RuO₄. In the first step, dispense metal oxide precursor ink step 132, an ink is dispensed on the surface of the substrate to form a feature 20 of a desired shape and size. In one example, as shown in FIG. 1, two features 20 that are rectangular in shape and have dimensions that are “W” long and “H” high were deposited on the surface 10 of the substrate 5.

Typically, the metal oxide precursor ink or adhesion coating contains both an organic and inorganic component, preferable in homogenous form and typically derived from single organometallic compounds. Particularly useful compounds or polymers containing titanium, zirconium, hafnium, vanadium, niobium, tantalum, molybdenum, tungsten, silicon, germanium, tin, lead, zinc, aluminum, gallium and indium, as well as their mixtures and combinations with other elements. In one aspect, a catalytic metal containing material that may be useful to perform this process, particularly when the substrate material is an oxidizable organic material, or polymeric material, is a perruthenate material (RuO₄⁻), such as sodium perruthenate (NaRuO₄) or potassium perruthenate (KRuO₄). In another aspect, the catalytic metal containing material is formed using a palladium (Pd) compound such as Pd²⁺ salt, selected so that it reacts with or firmly binds with the underlying substrate. In yet another aspect, the catalytic metal containing material contains a high oxidation state metal selected from a group consisting of osmium (e.g., osmium tetroxide (OsO₄)), iridium (e.g., iridium hexafluoride (IrF₆)), platinum (e.g., hexachloroplatinum (H₂PtCl₆)), cobalt, rhodium, nickel, palladium, copper, silver, and gold. Alternatively, the ink may be formulated by incorporating an inorganic or polymeric binding component that promotes good adhesion between a catalytic metal component and the substrate being patterning. In some embodiments, such adhesion may require a subsequent anneal or firing step at a temperature not incompatible with the stability of the underlying substrate.

This configuration is generally preferred for applications requiring robust adhesion to an oxide based dielectric or oxidized metal surface. For example, it is advantageous for patterning electrically conductive and electrochemically active regions over the surface of a metal, such as aluminum (Al), titanium (Ti), zirconium (Zr), hafnium (Hf), vanadium (V), niobium (Nb), tantalum (Ta), chrome (Cr), molybdenum (Mo), and tungsten (W), that is prone to the formation of insulating and passivating oxides layers by extended exposure to water, oxygen, or when exposed to anodic bias. The “ink” for such applications may contain a soluble metal alkoxide gel solution, which is hereafter referred to as a “sol gel”. A metal contained in the metal alkoxides may include an early transition metal, such as titanium, zirconium, hafnium, vanadium, niobium, tanatulum, molybdenum, tungsten, or a main group metal, such as silicon, germanium, tin, lead, aluminum, gallium, or indium. Such solutions are ordinarily obtained by dissolution of a metal alkoxide precursor in an alcohol based solvent to which sufficient water (H₂O) is added to induce partial hydrolysis and impart the desired degree of viscosity desired for effective printing. For example, an effective “ink” is obtained by the combination of 1 gram of titanium isopropoxide (Ti(OC₃H₇)₄), 20 grams of isopropanol, and between about 0 and about 0.1 gram of H₂O.

In one embodiment, to enhance adhesion it is preferable to expose the surface of the substrate to a preclean chemical solution to produce a hydrophilic metal hydroxide (M-OH) terminated surface prior to depositing the “ink”. In one example, a suitable preclean solution include mixtures of sulfuric acid (H₂SO₄) and 30% hydrogen peroxide (H₂O₂) followed by DI water rinse. In another example, where the substrate or exposed elements on the surface of the substrate are sensitive to acidic solutions, the preclean solution may contain mixtures of ammonia hydroxide (NH₄OH) and 30% hydrogen peroxide (H₂O₂).

It should be noted that embodiments of the invention also provide a method of forming a uniform, or blanket, coating over a surface of the substrate. To deposit a uniform, or blanket, coating of the “ink” on the substrate surface a conventional spin, dip, or spray coating process may be used. Such processes will generally allow the “ink” to readily spread and form a layer on the surface of the substrate.

In cases where a patterned layer, such as feature 20 in FIG. 1, is to be formed on the surface of the substrate an ink jet printing, silk screen, stencil printing, rubber stamp transfer, or any other similar printing process that has the required resolution may be used. In this case the selected ink should contain a functionality that is readily oxidized by the exposure to RuO₄ vapors, while the other exposed substrate surfaces should not react with the RuO₄ vapors. It is also desirable to select an ink that readily forms a strong and chemically inert bond between the substrate surface (e.g., dielectric surface, metal oxide surface) and to the RuO₂ coated feature 20 generated by the exposure to RuO₄ vapors.

One example of a desirable ink, are the metal alkoxide sol gel solutions, such as the titanium isopropoxide gel solution discussed above. It is believed that the H₂O generated by the oxidation of the “ink” containing the titanium isoproxide promotes the further cross-linking and densification of the titanium sol to generate an interpenetrating TiO₂—RuO₂ bilayer structure in which the formed layer containing TiO₂ serves as a robust adhesion layer between the substrate and the subsequently deposited RuO₂ layer. While there exists numerous applications using mixed metal oxide systems, such as RuO₂/TiO₂ and IrO₂/TiO₂, as dimensionally stable coatings for anodes in electrochemical cells the conventional techniques typically employed to form these mixed metal oxide layers are not amenable to the formation of a thin uniform and continuous blanket films. The methods described herein are able to form a continuous RuO₂ layer, due to the use of ruthenium tetroxide containing gas that is able to saturate the exposed surfaces during the deposition process. Typically, conventional mixed metal oxide formation processes use a paint “on”, brush “on” or other similar technique that requires a high temperature annealing or sintering process to form a mixed metal oxide film. The mixed metal oxide films formed using conventional processes are generally discontinuous and have multiple metal oxides exposed on the surface of the substrate, rather than a pure ruthenium oxide layer.

It should be noted that the processes described herein can be used to form other types of mixed metal oxides that contain a ruthenium metal oxide by an analogous vapor phase sequence or using a patterning process employing an oxidizable (e.g., by RuO₄) precursor to the other types of metal oxides. To promote adhesion and resolution of the feature 20 formed on a substrate, it is generally desirable for the thickness of the dried, metal oxide precursor containing ink layer be less than one micrometer (μm) in thickness, and more preferably less than 1000 Å. Generally, the minimum effective thickness is essentially that of a single adsorbed monolayer of the bound metal precursor. For example, in some embodiments, the ink may contain non-hydrolysable but readily oxidized substitutents, as exemplified by blanket vapor primed surfaces using dimethyldichlorotin or inks producing films of organo-tin materials. In this case the thickness of the adhesion layer precursor may be as thin as a single layer containing dimethyldichlorotin (Sn(CH₃)₂) (e.g., about 5 Å). In some aspects, a single atomic layer of RuO₂ may be sufficient to initiate the autocatalytic deposition of a much thicker conductive layer by a subsequent electroless plating process.

Optionally, in the next step, or remove organic components step 134, the organic component of the ink is removed following its application to the substrate surface. In one aspect, it is desirable to heat the substrate the ink deposited on it in an inert or vacuum environment to a temperature of about 200° C. to about 300° C. to cause most or all of any residual organic solvent to be removed and to promote the bonding of a catalytic precursor to the surface of the substrate. In one embodiment, particularly applicable to the patterning of readily oxidizable substrates, which are not compatible with image development by exposure to RuO₄, a patterning sequence employs disposing an aqueous or halocarbon solution containing RuO₄, or an aqueous alkali metal perruthenate salt solution of on various desired regions on the surface of the substrate. In one example, when forming aqueous solutions of a perruthenate salt it is advantageous to add at least an equivalent mass of a water soluble organic polymer shortly before applying the ink to improve ink transfer and drying characteristics. In such applications it is particularly useful to employ a heating step after the ink is dry (e.g., ≦250° C.) to help fixing the image and decompose the organic additive. A useful organic additive may be a low to medium molecular weight (50,000<Mw<1000) oligomers of poly(ethyleneoxide), commonly referred to as PEGs (polyethyleneglycols).

In the final step, or electrolessly deposit a conductive layer step 136, a conductive layer may be is deposited on the metallized layer formed in the step 132 or step 134. In this step the metallized feature 20 is exposed to an electroless chemistry (e.g., electroless copper bath) which causes the catalytic initiation of a subsequently autocatalytic plating process to form an electroless metal film covering the area initially defined by the catalytic ink. Step 136 is generally used to form a conductive layer on the metallized layer that has properties (e.g., thickness and conductive properties) that it can pass a desired current through the newly formed interconnect layer.

In another embodiment of the catalic ink deposition process, a perruthenate (NaRuO₄) or dilute RuO₄ containing solution “ink” is patterned on a plastic substrate to define the placement of a catalytic adhesion and initiation layer for the growth of an electroless interconnect on a plastic substrate. Typically, plastic substrates may include, but are not limited to polymeric materials, such as polyethylene, polypropylene, epoxy coated materials, silicones, polyimide, polystyrene, and cross-linked polystyrene. In this application, the ruthenium based solution “ink” is highly oxidizing and essentially “burns” its way into the surface of the plastic substrate. The process thus deposits a patterned RuO₂ layer which may serve as a catalytic seed and adhesion layer for subsequent plating using an electroless metal plating formulation. For such applications, the catalytic properties useful for electroless plating processes are generally improved by adding additional catalytic metals to the ink. For example, a perruthenate based ink may be formed by adding to the perruthenate based ink formulation up to an equivalent molar amount of a palladium nitrate solution in nitric acid. In addition, to avoid the “bleeding” of the ink deposited onto patterned areas it is advantageous to anneal the dried ink image. The annealing process may require annealing the ink in air to facilitate the oxidative patterning of the polymer surface and then under a reducing atmosphere such as forming gas. Other useful gas phase reducing agents include but are not limited to hydrazine or hydrazine hydrate, as well as various main group element hydride gases (e.g., phosphine (PH₃) silane (SiH₄) or diborane (B₂H₆). In one example, the application of a copper interconnect pattern on an ordinary (PET) viewgraph film using an ink jet printer can be accomplished using this process sequence, and is directly extendible to the application of interconnect features needed for flexible plastic displays or solar cells.

An attractive aspect of a RuO₂ or mixed Ru-metal oxide patterned feature is its use in conjunction with various thin transparent conductive oxide layers such at indium tin oxide (ITO) and zinc oxide (ZnO), with which it may provide an improved adhesion and lower contact resistance initiation layer for the patterned growth of electroless metal interconnects. In such cases, the selection of the optimum patterning sequence depends on the relative reactivity of those device layers exposed to RuO₄ containing gas. In general, if existing device layers are relatively inert to Ru0₄, the preferred patterning approach is to apply a ink containing easily oxidizable metal oxide precursor (usually containing a organic functionality) followed by exposure to RuO₄ vapors. However, in cases where the exposed substrate surfaces are reactive with Ru0₄, patterning using ink formulations containing either RuO₄ or mixtures containing ruthenate anions (e.g., RuO₄⁻¹ and RuO₄⁻²) are preferably used to form discrete catalytic regions.

Formation of Conductive Feature Using a Catalytic Precursor and a Patterned SAM Layer

In one embodiment, a conductive feature 20 is formed on the surface of the substrate by use of a SAM layer that is patterned on the surface 10 of the substrate 5 (FIG. 1). The first step is similar to the steps discussed above in conjunction with step 110 in FIG. 2, and thus generally includes the steps of depositing the SAM material by use of an inkjet, rubber stamping, or any technique for the pattern wise deposition (i.e., printing) of a liquid or colloidal media on the surface of a solid substrate. In one embodiment, this step is followed by a subsequent thermal post treatment (which may be advantageously performed under reduced pressure) or simply an amount of time sufficient to permit any solvent or excess coupling agent (i.e., a SAM precursor) to evaporate. In another embodiment, after a time or thermal treatment sufficient to achieve strong and selective bonding of a single monolayer to the substrate surface, excess material may be removed by rinsing with a suitable solvent and the pattern permitted to dry.

In the second and final step the surface of the substrate is exposed to a solution containing a catalytic metal precursor, such as a soluble palladium, ruthenium, rhodium, iridium, platinum, nickel or cobalt metal salt, to form a catalytic layer. To promote adhesion of the catalytic metal species to the substrate surface and to accelerate the initiation of subsequent electroless plating processes without the bleeding of the ink into the electroless bath, it is advantageous to follow the patterning step with exposure to a strong reducing agent, preferably a gas phase reducing agent, accompanied by sufficient heat to ensure the reduction of the catalytic ink layer to give atoms or clusters of the reduced metal. Gas phase reduction can be achieved by exposure to vapors of hydrazine, hydrazine hydrate, or simply a hydrogen containing gas at elevated temperatures generally higher than 250° C. Catalytic inks may also be reduced and rendered insoluble by use of a solution phase reaction using typical electroless plating reducing agents, such as DMAB (dimethylamine-borane), alkali metal borrohydride (BH₄⁻), hypophosphite (H₂PO₂⁻) salt, or glyoxylate solution (CHOCO₂⁻). In the simplest case, a substrate having a patterned catalytic metal containing ink, as described above, is transferred directly into an electroless plating formulation

Ruthenium Process Chemistry and Deposition Hardware

Embodiments of the invention generally provide a new chemistry, process, and apparatus to provide conformal and direct electrochemically or electrolessly platable ruthenium seed layers that avoid problems encountered with conventional metallization approaches. The strategy generally requires the use of the precursor RuO₄ that can be generated and delivered on demand using new hardware components. The reactive nature of Ru0₄ chemistry provides PVD like adhesion with ALD like conformality, and the catalytic properties of ruthenium off a robust initiation layer for electroless metallization of virtually any dielectric, barrier or metal substrate.

Ruthenium is currently the least expensive of the platinum group metals (PGMs) and exhibits many attractive features for use in the metallization of areas on a substrate surface. Ruthenium surfaces generally do not become passivated by the formation of an insulating oxide: Ruthenium dioxide will form in oxidizing environments, but exhibits metallic conductivity and is readily reduced back to ruthenium metal. The processes described herein exploit the unique properties and reactivity of ruthenium tetroxide (Ru0₄) to form a catalytically active, continuous coating over a surface of a substrate. Since ruthenium tetroxide has a melting point just slightly over room temperature (27° C.) and a vapor pressure near room temperature between about 2 and 5 Torr, it has many advantages over the prior art ruthenium deposition processes employing less volatile, less reactive, and more expensive ruthenium compounds.

When ruthenium tetroxide (Ru0₄) contacts surfaces over about 180° C. it is reported to undergo spontaneous decomposition to the thermodynamically more stable Ru0₂, which in turn forms metallic ruthenium by exposing the RuO₂ surface to hydrogen (H₂) at slightly higher temperatures. The balanced equation for the latter reaction can be written simply as equation (1) shown below.
RuO₄+H₂(excess)→Ru(metal)+4H₂O (1)

However, a particularly attractive feature of Ru0₄ chemistry for vapor phase patterning processes, is that initiation can occur in a stepwise fashion involving the selective oxidation of surface monolayers (typically below about 150° C.) as well as non-selectively (but also conformally) by unimolecular decomposition to RuO₂ and O₂ at higher temperatures. Subsequent reduction by exposing the RuO₂ surface to molecular hydrogen (H₂) at higher temperatures (e.g., ≧250° C.), a hydrogen plasma, or other volatile reducing agents then completes an ALD ruthenium cycle shown in equation (2a) and (2b) to provide a film of well controlled thickness without the potential inclusion of carbon or hydrocarbon ligand derived impurities correlated with typical organometallic precursors.
RuO₄+Substrate-H₂→Substrate-O—Ru0₂+H₂0 (2a)
Substrate-O—Ru0₂+H₂(excess)→Substrate-O—Ru(metal)+2H₂0 (2b)

Ruthenium tetroxide (RuO₄) is generally stable up to at least 100° C. for short periods of time in the absence of a reactive surface, but over about 180° C. it decomposes to RuO₂ releasing O₂. The propensity of pure RuO₄ to decompose has restricted its sale, shipping, and storage. Therefore, an on-demand generation and/or purification and delivery process for Ru0₄, is required. One approach to this is indicated in equation (3).
Ru(metal)+2O₃→RuO₄+O₂ (3)
A notable and unusual feature of this reaction is that Ru0₄ can be the primary kinetically preferred product, while Ru0₂ is thermodynamically more stable and represents a dead end. Since the reaction is not completely selective, surfaces of ruthenium can eventually become passivated with Ru0₂ and require regeneration. Regeneration can be accomplished by exposure to a downstream H₂ plasma or simply by cycling over 250° C. under forming gas.

One embodiment of a processing chamber that can be used to deposit a ruthenium containing layer (e.g., RuO₂, Ru(metal)) is illustrated in FIG. 5. An exemplary method and apparatus for generating and forming a ruthenium containing layer on a substrate surface is further described in the commonly assigned U.S. patent application Ser. No. 11/228,425 [APPM 9906], filed Sep. 15, 2005, the commonly assigned U.S. patent application Ser. No. 11/228,629 [APPM 9906.02], filed Sep. 15, 2005, and the commonly assigned U.S. Provisional Patent Application Ser. No. 60/792,123 [APPM 11086L], filed Apr. 14, 2006, which are all herein incorporated by reference in their entirety. The process step(s) used to deposit a ruthenium layer on a surface of a substrate could be performed on a Producer™ platform available from Applied Materials Inc., of Santa Clara, Calif.

FIG. 5 illustrates one embodiment of a process chamber 603 that may be adapted to deposit a ruthenium containing layer on the surface of a substrate using a ruthenium containing gas. The configuration shown in FIG. 5 may be useful to deposit the ruthenium containing layer as described above (e.g., “Coupling Agent Approach” process, “Patterned SAM Layer” process, “Interconnect Process”) and the processes described below. The deposition chamber 600 generally contains a process gas delivery system 601 and a processing chamber 603. One will note that the process gas delivery system 601 shown in FIG. 5 is used in conjunction with the ruthenium tetroxide generation techniques described below. It should be noted that the methods discussed below are not intended to be limiting as to the scope of the invention. A method of generating a ruthenium tetroxide gas by use of a ozone containing gas and ruthenium metal (or a perruthenate) is further described in the commonly assigned U.S. patent application Ser. No. 11/228,425 [APPM 9906], filed Sep. 15, 2005, the commonly assigned U.S. patent application Ser. No. 11/228,629 [APPM 9906.02], filed Sep. 15, 2005, and the commonly assigned U.S. Provisional Patent Application Ser. No. 60/792,123 [APPM 11086L], filed Apr. 14, 2006, which are all herein incorporated by reference in their entirety.

FIG. 5 illustrates one embodiment of a process chamber 603 that may be adapted to deposit the ruthenium containing layers on the surface of a substrate. In one aspect, the process chamber 603 may be adapted to deposit a layer, such as a barrier layer, on the surface of the substrate by use of a CVD, ALD, PECVD or PE-ALD process prior to depositing a ruthenium containing layer on the surface of the substrate. In another aspect, the processing chamber 603 is adapted to primarily deposit the ruthenium containing layer and thus any prior or subsequent device fabrication steps are performed in other processing chambers. In one aspect, the prior or subsequent processing chambers and the processing chamber 603 are attached to a cluster tool (not shown) that is adapted to perform a desired device fabrication process sequence. For example, in process sequences where a barrier layer is deposited prior to the ruthenium containing layer, the barrier layer may be deposited in an ALD process chamber, such as the Endura iCuB/S™ chamber or Producer™ type process chamber, prior to forming the ruthenium containing layer in the processing chamber 603. In yet another aspect, the processing chamber 603 is a vacuum processing chamber that is adapted to deposit the ruthenium containing layer at a sub atmospheric pressure, such as a pressure between about 0.1 mtorr and about 50 Torr. The use of a vacuum processing chamber during processing can be advantageous, since processing in a vacuum condition can reduce the amount of contamination that can be incorporated in the deposited film. Vacuum processing will also improve the diffusion transport process of the ruthenium tetroxide to the surface of the substrate and tend to reduce the limitations caused by convective type transport processes. In one embodiment, it is desirable to vary the pressure in the process chamber during processing between 0.1 mtorr and about atmospheric pressure.

The processing chamber 603 generally contains a processing enclosure 404, a gas distribution showerhead 410, a temperature controlled substrate support 623, a remote plasma source 670 and a gas source 612B connected to an inlet line 671, and a process gas delivery system 601 connected to the inlet line 426 of the processing chamber 603. The processing enclosure 404 generally contains a sidewall 405, a ceiling 406 and a base 407 enclose the processing chamber 603 and form a process area 421. A substrate support 623, which supports a substrate 422, mounts to the base 407 of the processing chamber 603. A backside gas supply (not shown) furnishes a gas, such as helium, to a gap between the backside of the substrate 422 and the substrate support 623 to improve thermal conduction between the substrate support 623 and the substrate 422. In one embodiment of the deposition chamber 600, the substrate support 623 is heated and/or cooled by use of a heat exchanging device 620 and a temperature controller 621, to improve and control properties of the ruthenium layer deposited on the substrate 422 surface. In one aspect, the heat exchanging device 620 is a fluid heat exchanging device that contains embedded heat transfer lines 625 that are in communication with a temperature controlling device 621 which controls the heat exchanging fluid temperature. In another aspect, the heat exchanging device 620 is a resistive heater, in which case the embedded heat transfer lines 625 are resistive heating elements that are in communication with the temperature controlling device 621. In another aspect, the heat exchanging device 620 is a thermoelectric device that is adapted to heat and cool the substrate support 623. A vacuum pump 435, such as a turbo-pump, cryo-turbo pump, roots-type blower, and/or rough pump, controls the pressure within the processing chamber 603. The gas distribution showerhead 410 consists of a gas distribution plenum 420 connected to the inlet line 426 and the process gas supply 425. The inlet line 426 and gas supply 425 are in communication with the process region 427 over the substrate 422 through plurality of gas nozzle openings 430.

In one aspect of the invention it may be desirable to generate a plasma during the deposition process to improve the deposited ruthenium containing layer's properties. In this configuration, the showerhead 410, is made from a conductive material (e.g., anodized aluminum, etc.), which acts as a plasma controlling device by use of the attached to a first impedance match element 475 and a first RF power source 490. A bias RF generator 462 applies RF bias power to the substrate support 623 and substrate 422 through an impedance match element 464. A controller 480 is adapted to control the impedance match elements (i.e., 475 and 464), the RF power sources (i.e., 490 and 462) and all other aspects of the plasma process. The frequency of the power delivered by the RF power source may range between about 0.4 MHz to greater than 10 GHz. In one embodiment dynamic impedance matching is provided to the substrate support 623 and the showerhead 410 by frequency tuning and/or by forward power serving. While FIG. 5 illustrates a capacitively coupled plasma chamber, other embodiments of the invention may include inductively coupled plasma chambers or combination of inductively and capacitively coupled plasma chambers with out varying from the basic scope of the invention.

In one embodiment, the processing chamber 603 contains a remote plasma source (RPS) 670 that is adapted to deliver various plasma generated species or radicals to the processing region 427. An RPS that may be adapted for use with the deposition chamber 600 is an Astron® Type AX7651 reactive gas generator from MKS ASTeX® Products of Wilmington, Mass. The RPS is generally used to form, reactive components, such as hydrogen (H) radicals, which are introduced into the processing region 427. The RPS thus improves the reactivity of the excited gas species to enhance the reaction process. A typical RPS process may include using 1000 sccm of H₂ and 1000 sccm of argon and an RF power of 350 Watts and a frequency of about 13.56 MHz. In one aspect a forming gas, such as a gas containing 4% H₂ and the balance nitrogen may be used. In another aspect a gas containing hydrazine (N₂H₄) may be used. In general, the use of plasma excitation to generate reducing species capable of converting RuO₂ to Ru will allow the reaction to proceed at lower temperature and may be most useful when it is desired to deposit the RuO₂ selectively, below approximately 180° C., on a predefined pattern (for example a ink-jet defined image using a conventional ink or SAM derived from a silane coupling agent such as APTES) and then subsequently perform the reduction to Ru at the same temperature and/or in the same chamber. Generally, the disadvantage of such a process, relative to a purely thermal process, involve chamber complexity and more potential for particle deposition and less selective Ru deposition on the chamber walls.

Alternate Ruthenium Tetroxide Generation Process

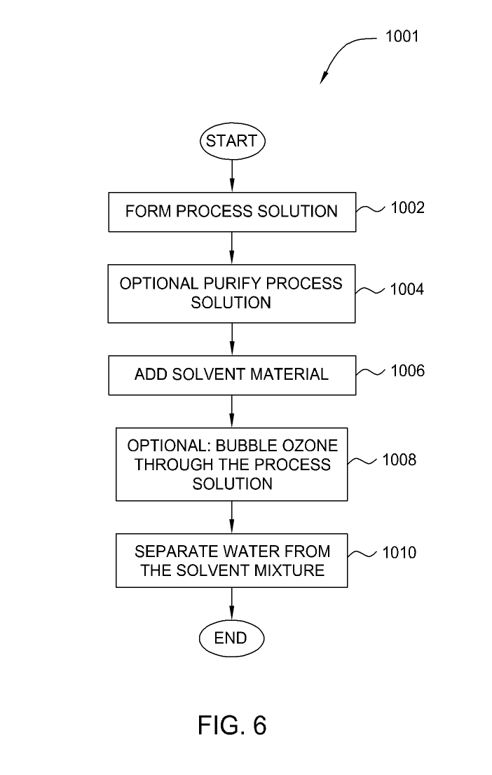

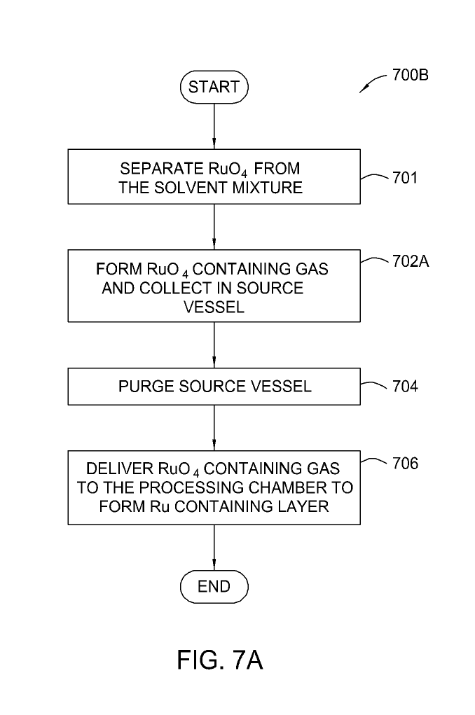

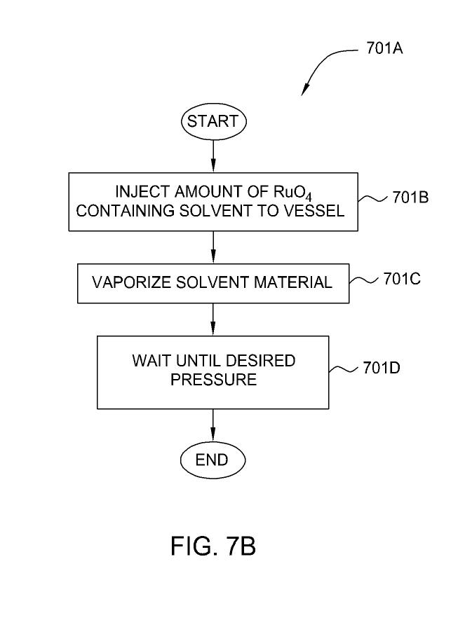

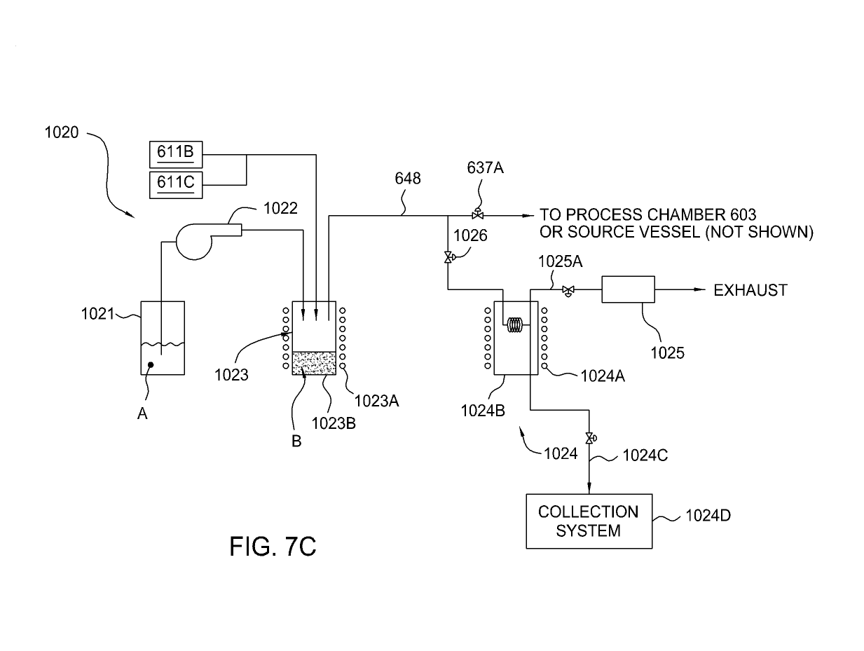

FIG. 6 illustrates one embodiment of a ruthenium tetroxide containing solvent formation process 1001 that may be used to form ruthenium tetroxide using a perruthenate containing source material (e.g., sodium perruthenate (NaRuO₄), or potassium perruthenate (KRuO₄)). The first step of the aqueous separation process (element 1002) starts by first dissolving a perruthenate material, such as sodium perruthenate in an aqueous solution in a first vessel (e.g., element 1021 in FIG. 7C). In one another embodiment, the a process solution may be formed by dissolving ruthenium metal in a solution of excess sodium hypochlorite (NaOCl) followed by titration with sulfuric acid to a pH value near 7 to liberate ruthenium tetroxide. One will note that hypochlorite materials, such as potassium or calcium hypochlorite, may also be used in place of the sodium hypochlorite. The ruthenium tetroxide is likely formed according to reaction (4).
2NaRuO₄+H₂SO₄+NaOCl→2RuO₄+NaCl+H₂0+Na₂SO₄ (4)
In one example, a process solution was formed by mixing 50 ml of a sodium hypochlorite (e.g., 10% NaOCl solution) with 1 gram of finely powdered ruthenium metal and stirring until dissolution is essentially complete. A sufficient amount of 10% solution of H₂SO₄ in water was then added to achieve a pH of about 7. In general, any acid that is non-oxidizable and non-volatile can be used in place of the sulfuric acid, such as phosphoric acid (H₃PO₄).

In one embodiment of the ruthenium tetroxide containing solvent formation process 1001, an additional purification step 1004 may next be performed on the process solution. The step 1005 generally includes the steps: 1) warming the process solution mixture to temperature of about 50° C. in a first vessel, and 2) bubbling an inert gas or ozone (O₃) through the process solution to deliver the vapor generated in the first vessel to a cooled second vessel (e.g., ≦20° C.) where the generated vapor condenses giving a mixture of ruthenium tetroxide and water. The ruthenium tetroxide vapor generated in the first vessel will thus be collected in the pure water contained in the second vessel. It should be noted that after completion of step 1004 the second vessel will contain the aqueous solution components that the rest of the ruthenium tetroxide containing solvent formation process 1001 steps will use, while the left over components in the first vessel can be discarded or reclaimed. Step 1004 may be useful to help purify the process solution which will be used as the ruthenium tetroxide source material.

In step 1006 an amount of a solvent is added to the aqueous solution to solubilize all of the Ru0₄ contained in the aqueous solution. Suitable solvents generally include the materials such as perfluorocarbons (CₓF_{y}), hydrofluorocarbons (HₓC_{y}F_{z}), and chlorofluorocarbons (e.g., Freons or CFCs.). In general any solvent material that is non-polar, non-oxidizable and has a boiling point near and more preferably below about 50° C. may be useful to perform this process. Preferably, the boiling point of the solvent is between about ca. 25° C. and about 50° C. In general, while both Freon's and perfluorocarbons are effective, perfluorocarbons, shown not to behave as ozone depleting substances (ODS) are preferred. A suitable solvent, for example, is perfluoropentane (C₅F₁₂), or perfluorohexane (C₆F₁₄). Also, a Freon such as Freon 11 (CFCl₃)), or Freon 113 (1,1,2-trichloro-1,2,2-trifluoroethane (CCl₂FCClF₂)) or various common refrigerants may be employed as the solvent, particularly if the entire process can be performed within a sealed system capable of preventing their release into the environment. Perfluoropentane may have many advantages for use in the semiconductor industry since it can easily be purchased in a pure form, it is not an “ozone depleting substance”, and it is extremely inert and thus will generally not react with the materials it is exposed to during processing.

In one embodiment of the ruthenium tetroxide containing solvent formation process 1001, an optional step 1008 may next be completed on the solvent mixture formed in step 1006. This step adds the action of bubbling ozone (O₃) through the solvent mixture contained in the first vessel (e.g., element 1021 FIG. 7C), which is maintained at a temperature preferably near room temperature to assure complete formation of ruthenium tetroxides. An example of a ruthenium tetroxide generation step includes flowing 4% ozone containing gas at a rate of 500 ml/min through the mixture containing 1 gram of sodium perruthenate, 50 milliters of water and 25 g of Freon 113 until a desired amount of ruthenium tetroxide is formed.

The final step 1010 of the ruthenium tetroxide containing solvent formation process 1001 generally requires the step of separating the water from the solvent mixture formed after completing steps 1006 and/or 1008 to form an “anhydrous” solvent mixture. In one aspect, by choosing a solvent that is not miscible with water allows the water to be easily removed from the solvent mixture by use of some conventional physical separation process. Failure to separate most, if not all, of the water from the rest of the solvent mixture may cause problems in the subsequent process steps and can decrease the selectivity of the Ru0₄ towards deposition on a patterned layer. If the selected solvent is not miscible with water and has a different density than water, such as perfluoropentane, Freon 11 or Freon 113, most of the water can be easily separated from the static mixture by use of simple mechanical techniques (e.g., a separatory funnel, siphon or pump). A complete removal of the residual water may be accomplished by contacting the liquid with a molecular sieve (e.g., 3A molecular sieves) followed by conventional filtration using a porous membrane or fabric relatively inert towards RuO₄, suitable examples of which include Teflon membranes or glass fiber fabric. The anhydrous” solvent mixture can then be transferred into a standard CVD precursor source apparatus for use on a tool and process in which the ruthenium containing layer is to be deposited. It is important to note that pure solid ruthenium tetroxide is generally unstable which makes it difficult to handle and hard to transport from one place to another. Therefore, one benefit of the invention described herein is it creates a way to effectively transport and/or generate ruthenium tetroxide that can be used to form a ruthenium containing layer. In one aspect, it may be desirable to ship and place the ruthenium tetroxide in an environment that has no exposure to light to prevent decomposition of the ruthenium tetroxide to ruthenium dioxide and oxygen.

In one embodiment, it may be important to assure that all of the contaminants are removed from the “anhydrous” solvent mixture to prevent or minimize contamination of the substrate surface during a subsequent ruthenium containing layer deposition process steps. In one aspect, to assure that all or most of the contaminants are removed, various purification processes may be completed on the “anhydrous” solvent mixture before the mixture or its components are ready to be exposed to a substrate surface. In one aspect, the purification process may include completing the process step 1004 on the process solution formed in step 1002 at least once. In another aspect, the process step 1010 in the ruthenium tetroxide containing solvent formation process 1001 is completed on the process solution at least once.

Forming a Ruthenium Layer Using a Ruthenium Tetroxide Containing Solvent

After performing the ruthenium tetroxide containing solvent formation process 1001 the “anhydrous” solvent mixture is then used to form a ruthenium containing layer on a surface of the substrate by use of a process 700B illustrated in FIG. 7A. In this embodiment, the process 700B contains process steps 701-706. In other embodiments, the steps found in process 700B may be rearranged, altered, one or more steps may be removed, or two or more steps may be combined into a single step without varying from the basic scope of the invention. For example, in one embodiment, the process step 704 is removed from the process 700B.

The first step of process 700B, or step 701, requires the separation of the ruthenium tetroxide from the rest of the “anhydrous” solvent mixture. In one embodiment, step 701 is a series of process steps (see process sequence 701A in FIG. 7B) that may utilize a separation hardware system 1020 (see FIG. 7C) to separate the ruthenium tetroxide from the rest of the “anhydrous” solvent mixture. FIG. 7B illustrates one embodiment of a process sequence 701A that may be used to perform process step 701. The process sequence 701A starts by delivering and connecting a first vessel 1021 that contains the “anhydrous” solvent mixture (element “A”) formed using the ruthenium tetroxide containing solvent formation process 1001 to a processing vessel assembly 1023. The hardware shown in FIG. 7C is intended to be able to deliver a ruthenium tetroxide containing gas to a processing chamber. The processing vessel assembly 1023 generally contains a processing vessel 1023B and temperature controlling device 1023A (e.g., fluid heat exchanging device, a resistive heating device and/or a thermoelectric device).

The first step (step 701B) of the process sequence 701A starts by injecting a desired amount of the “anhydrous” solvent mixture, into a processing vessel 1023B by use of a metering pump 1022 or other conventional fluid delivery process. The processing vessel 1023B is then evacuated to a desired temperature and pressure (step 701C) by use of the temperature controlling device 1023A, a vacuum pump 1025 and/or one or more gas sources 611B-C so that the solvent, which has a higher vapor pressure than the ruthenium tetroxide, will vaporize and thus be separated from the ruthenium tetroxide material that is retained in the processing vessel 1023B (element “B” FIG. 7C). For example, if Freon 113 is used as the solvent material, temperatures of less than about 0° C. and pressures of about 360 Torr can be used to separate the solidified ruthenium tetroxide from the solvent mixture. Low pressures, such as about 3 Torr, may be used to perform the separation process, but a larger amount ruthenium tetroxide will be carried away with the solvent, and thus lost, as the pressure used to complete this step is lowered.

The last step of the process sequence 701A, step 701D, generally requires that the processing vessel 1023B be evacuated until the pressure in the processing vessel reaches a desired level or until the pressure in the vessel stabilizes. In general, step 701D is performed until only small amounts of solvent, left over water and/or other solubilized foreign materials are left in the processing vessel 1023B. Failure to adequately separate the other materials from the ruthenium tetroxide material may cause contamination of the ruthenium containing layer formed during subsequent deposition process(es). In one aspect, it may be advantageous to control the temperature in the processing vessel 1023B to cause the solvent and other materials to be removed.

In one aspect of the process sequence 701A, a cold trap assembly 1024 is used to collect and reclaim the vaporized solvent material created as the processing vessel 1023B is evacuated by the vacuum pump 1025. The cold trap assembly 1024 is adapted to cool a portion of the vacuum line 1025A to a temperature that will cause the vaporized solvent material to condense so that in a subsequent step the condensed solvent can be reclaimed in a collection tank/system 1024D. The cold trap assembly 1024 generally contains a collection region 1024B of chilled vacuum line 1025A, an isolation valve 1026, a temperature controlling device 1024A (e.g., fluid heat exchanging device, a resistive heating device and/or a thermoelectric device) and a collection line 1024C connected to a solvent collection tank/system 1024D. In one aspect, any collected ruthenium tetroxide found in the condensed solvent is reclaimed.

After performing step 701 the separated ruthenium tetroxide, which is contained in processing vessel 1023B, can then be used to form a ruthenium containing layer on a surface of the substrate by use of process step 702A (FIG. 7A). Process step 702A requires controlling the temperature of the ruthenium tetroxide material contained in the processing vessel 1023B and the pressure inside the processing vessel 1023B to cause the leftover solid ruthenium tetroxide to vaporize, so that it can be delivered to the processing region of a deposition chamber. In one embodiment, in step 704 the leftover solid ruthenium tetroxide is vaporized and then condensed and collected in a source vessel (not shown) that is positioned between the processing vessel 1023B and the processing chamber (e.g., element 603 in FIG. 5). During step 704 the non-condensing gases are purged from the source vessel using a flow an inert gas. At the end of step 704 the condensed RuO₄ is then be vaporized and delivered to a process chamber in a more purified form. The term vaporize as used herein is intended to describe the process of causing a material to be converted from a solid or liquid to a vapor. In one example, the ruthenium tetroxide material is maintained at a temperature of about 25° C. and the process chamber evacuated to it's base pressure, generally under about 0.1 Torr, after which a valve between the RuO₄ and the process chamber is opened to promote transfer of RuO₄ vapors into the process chamber without a carrier gas. Referring to FIG. 7C, in one aspect, the vaporized ruthenium tetroxide is carried by a flow of an inert carrier gas delivered from the one or more gas sources 611B-C through the processing vessel 1023B, a process line 648 and valve 637A to the process chamber (not shown) or source vessel(s) (not shown). The concentration and flow rate of the ruthenium tetroxide containing gas is related to the process gas flow rate and the vaporization rate of the ruthenium tetraoxide in the processing vessel 1023B. The vaporization rate is related to the equilibrium partial pressure of ruthenium tetroxide at the pressure and temperature maintained in the processing vessel 1023B. After performing step 702A a ruthenium containing layer can be deposited on a substrate surface by following the steps described in the Ruthenium Process Chemistry And Enabling Hardware section above. In one embodiment, multiple sequential doses of ruthenium tetroxide are delivered to the process chamber (not shown) to form a multilayer ruthenium containing film. To perform the multiple sequential doses at least one of the process steps 701 through 706, described in conjunction with FIG. 7A, are repeated multiple times to form the multilayer ruthenium containing film. In another embodiment, a continuous flow of a desired concentration of a ruthenium tetroxide containing gas is delivered across the surface of the substrate during the ruthenium containing layer deposition process. To facilitate the most efficient utilization of RuO₄ vapor it can be preferable to evacuate the entire deposition system to its baseline and to refill it with only that amount of RuO₄ vapor required to deposit a desired film thickness.

Deposition Process Using an Anhydrous Solvent Mixture

In one embodiment of a process of forming a ruthenium containing layer on a surface of a substrate, the “anhydrous” solvent mixture formed in the ruthenium tetroxide containing solvent formation process 1001 is directly delivered to a surface of a substrate positioned in the processing chamber 603 (see FIG. 5). In one aspect, an inert solvent, such as perfluoropentane (C₅F₁₂), which will generally not react with RuO₄, the metal alkoxide/oxide precursor ink or the substrate being patterned, is employed to stabilize Ru0₄ and facilitate the metering of the mixture to the processing chamber 603. Referring to FIG. 5, in this embodiment, a ruthenium containing layer is formed on a surface of a heated substrate by delivering the vapors of both RuO₄ and the inert solvent used to the surface of the substrate positioned in the process region 427 of the processing chamber 603. As the temperature of the heated substrate is increase above about 100° C. the effectiveness of a selective deposition of RuO₂ only on areas patterned with the “ink” is decreased and deposition of RuO₂ proceeds non-selectively across all surfaces heated above approximately 180° C.

Referring to FIG. 5, in one embodiment, a desired amount, or mass, of the purified solvent mixture (element “A”) is delivered to the process region 427 by use of a carrier gas delivered from the gas source 611B and a hydrogen (H₂) containing gas (e.g., hydrogen (H₂)) to form a ruthenium layer on the surface of the substrate. In one aspect, in place of hydrogen, the reducing co-reactant may be hydrazine (N₂H₄) which is entrained in an inert carrier gas such as N₂. In one aspect, the carrier gas is delivered from the gas source 611C through a first vessel 1021, which contains the “anhydrous” solvent mixture and then directly through outlet line 660 and to a substrate 422 positioned in the process region 427 of the process chamber 603. In another embodiment, multiple sequential doses of the “anhydrous” solvent mixture are delivered to the process chamber 603 to form a multilayer ruthenium containing film. To perform the multiple sequential doses, a desired amount of the “anhydrous” solvent mixture is sequentially delivered to the substrate multiple times to form the multilayer ruthenium containing film.

In another embodiment, a continuous flow of the “anhydrous” solvent mixture is adapted to flow across the surface of the substrate 422 during the ruthenium containing layer deposition process. In one aspect, the “anhydrous” solvent mixture flows past the surface of the substrate and is collected by the vacuum pump 435. In one aspect, a cold trap assembly 1024 (FIG. 7C) and collection tank/system 1024D (FIG. 7C) are in fluid communication with the process region 427 and the vacuum pump 435 to collect any leftover “anhydrous” solvent mixture components, such as the solvent and any unreacted ruthenium tetroxide.

Vapor Phase Mixed Metal Oxide Film Deposition Process

In one embodiment, one or more layers of ruthenium dioxide (RuO₂) together with and a another metal oxide, such as titanium dioxide (TiO₂), tin oxide (SnOₓ; x=1 or 2) or zinc oxide (ZnOₓ; x=1 or 2), a tungsten oxide (WₓO_{y}), a zirconium oxide (ZrₓO_{y}), a hafnium oxide (HfₓO_{y}), a vanadium oxide (VₓO_{y}), a tantalum oxide (TaₓO_{y}), or an aluminum oxide (AlₓO_{y}), is are deposited over the surface 10 of a substrate 5 to create a conductive layer exhibiting enhanced adhesion and corrosion resistance. This configuration is useful for applications where the layers are exposed to aggressive oxidizing media. In general, the metal oxide layers can be formed from metals found in group III, groups IV, and the transition metals. For processes in which a thicker and more conductive layer of the mixed ruthenium dioxide and metal oxide film is desired the thicknesses may be readily increased by sequential exposures alternating between a volatile metal oxide precursor and a ruthenium tetroxide containing gas. For example, this process is readily implemented by alternating between vapor phase exposures to titanium isopropoxide (Ti(OC₃H₇)₄) and ruthenium tetroxide, both introduced into the evacuated process chamber either without dilution or in a stream of an inert carrier gas, depending largely on the volatility of the selected precursor.

Referring to FIG. 5, in one embodiment a gas source assembly 250 containing a plurality of gas sources 251, 252 are adapted to deliver a deposition gas to the inlet line 426, process region 427 and substrate 422. Each of the gas sources 251, 252 may also contain a number of valves (not shown) that are connected to the controller 480 so that a ruthenium containing gas can be delivered from the process gas delivery system 601 (FIG. 5), and/or a deposition gas can be delivered from the gas sources 251, 252.

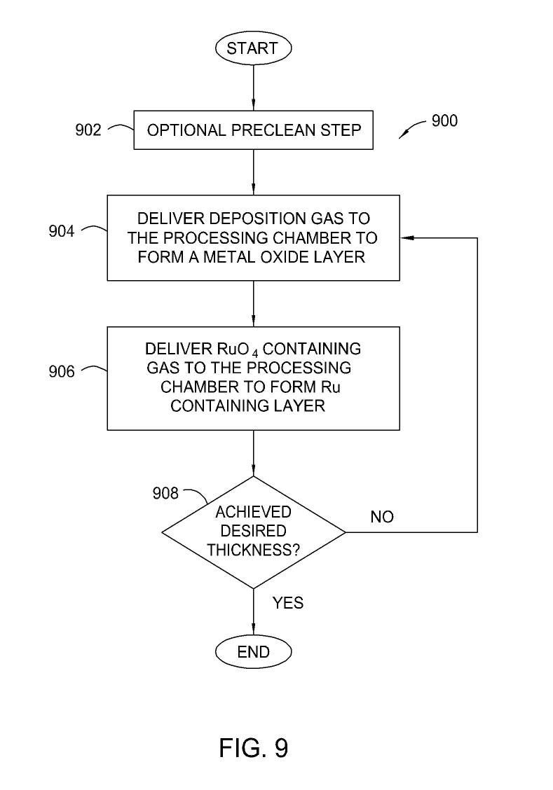

FIG. 9 depicts a process sequence 900 according to one embodiment described herein for forming a coating contain multiple layers of a metal oxide and a ruthenium containing layer on a surface of a substrate 422. Process sequence 900 includes steps 902-908, wherein the metal oxide and ruthenium containing layer(s) are directly deposited on surface of a substrate by use of a vapor phase volatile metal oxide precursor and ruthenium tetroxide containing gas can be advantageously used.

In step 902, an optional, preclean step is performed to pretreat the substrate surfaces to increase hydrophilic surface functionality, such as Si—OH moieties, which can subsequently react with the metal alkoxides to generate bound metal oxide precursor. An example of a suitable preclean solution is described above.

In step 904, a metal oxide layer is deposited on the surface of the substrate by delivering a deposition gas to the surface of the substrate from a gas source, such as gas source 251 shown in FIG. 9. In one aspect, the substrate is positioned on a temperature controlled substrate support 623 which is maintained at a temperature between about 20° C. and about 100° C. It should be noted that while the process sequence 900 described herein begins with the deposition of a metal oxide layer, other than a ruthenium containing layer, this configuration is not intended to limiting as to the scope of the invention described herein. In one example, when a plastic substrate (e.g., polyethylene substrate) is being used it is often desirable to first form a ruthenium containing layer before the metal oxide layer, due to ruthenium tetroxide's ability to react with the polymer substrate material to generate reactive functionality with which the other metal precursor, such an alkoxide, can readily react.

In one embodiment, the metal oxide layer contains a titanium dioxide, a tungsten oxide, a zirconium oxide, a hafnium oxide, a vanadium oxide, a tantalum oxide, an aluminum oxide, a tin oxide or a zinc oxide material that is deposited using a deposition gas delivered from a gas source assembly 250. In general the metal oxide and/or the ruthenium dioxide layer may be deposited or formed on the substrate by use of a chemical vapor deposition (CVD) or atomic layer deposition (ALD) process, although, one or the other can be initially deposited in a patternwise process (using any of the techniques previously described) by employing a metal oxide containing ink precursor. In another embodiment, the entire substrate surface may be coated (uniformly or otherwise) with a metal oxide precursor containing solution, prior to subsequent single or multiple vapor phase treatments to provide a robust, adherent, and corrosion resistant coating, which consistent with the procedures described for generating conductive patterns, may be applied to virtually any substrate type.

In one example, a Si—OH terminated silicon dioxide substrate surface created in step 902 is exposed to vapors of titanium isopropoxide, which results in a monolayer or more of adsorbed Si—O—Ti(i-OPr)ₓ functionality primed for subsequent reaction involving oxidation by Ru0₄ with the hydrolysis of any residual isopropoxide groups by the resulting water. In this example, a titanium dioxide layer may be deposited on the surface of the substrate using a deposition gas containing about 0.1% to about 100% titanium isopropoxide (Ti[OCH(CH₃)₂]₄) and the balance being an inert carrier gas, such as argon or nitrogen. The deposited titanium dioxide precursor layer may be between about 2 angstroms (Å) and about 500 Å thick. Typically, the processing chamber pressure is maintained at a total pressure below about 10 Torr and the substrate is heated to a temperature between about 25° C. and about 200° C., and more preferably less than about 100° C.

In another example, the metal oxide layer is formed using conventional titanium precursors, such as titanium tetrachloride (TiCl₄), TDEAT (tetrakis diethylaminotitanium) and TDMAT (tetrakis dimethylaminotitanium). In yet another example, the metal oxide layer is formed metals such as tin, tungsten, zirconium, hafnium, vanadium, tantalum, and aluminum using a conventional precursors, such as tin isopropoxide, tetramethyltin, tetrakis-dimethylaminotin, tungsten (V) ethoxide, tungsten (VI) ethoxide, zirconium isopropoxide, zirconium tetrakis-dimethylaminddimethylamide, hafnium tetrakis-ethylmethylamindethylmethylamide, hafnium tetrakis-dimethylamide, hafnium tetra-t-butoxide, hafnium tetraethoxide, vanadium tri-isopropoxide oxide, niobium (V) ethoxide, tantalum (V) ethoxide, and trimethylaluminum. The deposited layer may be subsequently oxidized to form a metal oxide layer or an oxidizing material may be injected into the processing region of a chamber during the deposition process. In one example, the titanium layer is subsequently oxidized using a gas that contains a small amount of water vapor (ppm range) which is delivered to the surface of the substrate, which is maintained at an elevated temperature, such as about 100° C.

In one embodiment of the step 904, the metal oxide layer is deposited on a substrate that has a conductive surface using an electrochemical process. In one example, a titanium layer is formed on the substrate using an a conventional PVD technique. The formed titanium layer can then be oxidized by heating the substrate and exposing it to an oxidizing gas (e.g., 50-250° C.). In another example, a tin layer is formed on the substrate using an electrolyte solution that contains stannic chloride (SnCl₄) using conventional electrochemical plating techniques. The formed tin layer can then be oxidized by heating the substrate and exposing it to an oxidizing gas. In yet another embodiment, a zinc layer is formed on the substrate using an electrolyte solution that contains zinc sulfate ZnSO₄ or from the vapor phase using chloride (ZnCl₂) or diethylzinc (Zn(C₂H₅)₂) using conventional electrochemical plating techniques. The formed metal layers undergo oxidation when exposed to a RuO₄ containing gas in a process which can generate a conductive contact.

In step 906, a ruthenium containing layer is directly deposited on surface of the substrate using a ruthenium tetroxide containing gas delivered from a ruthenium tetroxide source, such as a process gas delivery system 601 discussed above in FIG. 5. The step 906 may contain all of the steps described in process 700B depicted in FIG. 7A, which is used to deposit a ruthenium containing layer on the surface of the substrate. Step 906 is generally used to form a thin mixed ruthenium-metal oxide films that can act as an adhesion and initiation layer for subsequent metallization by electroless plating. In one example, a ruthenium dioxide layer is deposited on the surface of the substrate that are maintained at a temperature less than about 100° C. using a deposition gas containing about 0.1% to about 100% ruthenium tetroxide and the balance being an inert carrier gas, such as argon or nitrogen. In this example the ruthenium dioxide layer may be between about 2 angstroms (A) and about 50 Å thick. Typically, the processing chamber pressure is maintained at a total pressure below about 10 Torr and the substrate is heated to a temperature between about 25° C. and about 200° C. Preferably the temperature is less than about 100° C., if a selective deposition process is desired over a surface covered using one of the previously described strategies using a metal oxide precursor containing ink.

In one aspect, it is desirable to reduce the oxidation state of the ruthenium in the formed mixed metal oxide from +4 (it's value in RuO₂) to some lower value. This can be readily accomplished by adding an additional vapor phase sequence following the deposition of RuO₂ from RuO₄ which involves treatment with a volatile reducing agent in either the same or a different process chamber. In one example, molecular hydrogen is used as the reducing agent. To increase the activity of the reducing agent, such as hydrogen, it may be desirable to heat the substrate (e.g., >200) ° C. or by creating a plasma discharge so as to achieve interaction of the RuO₂ bearing substrate surfaces with hydrogen ions, radicals, and electrons. Alternatively, the reduction of RuO₂ can be accomplished at lower temperatures (including ambient room temperature) by selection of a more reactive volatile reducing agent. Suitable reducing agents for producing a reduced ruthenium surface at temperatures less than 100° C. include vapors of hydrazine or hydrazine hydrate, or by reaction with various main group element hydride gases, such as phosphine (PH₃), silane (SiH₄), or diborane (B₂H₆), though in such cases the product will incorporate solid oxidation products derived from the reducing agent.

Finally, in step 908, based on a desired number of cycles in which steps 902 and 904 are repeatedly performed, or a desired conductivity of the coating containing the metal oxide and ruthenium dioxide layers has been achieved, the process sequence 900 will be ended. In one example, only a single layer of a metal oxide and single layer of ruthenium dioxide are deposited on the surface of the substrate. In another example multiple metal oxide and ruthenium dioxide layers are deposited until the total coating thickness is between about 50 Å and about 10,000 Å.

In another embodiment, a metal oxide (e.g., TiO₂, SnO₂, ZnO₂) and ruthenium dioxide are co-deposited to form a layer that contains a desired percentage of the metal oxide and ruthenium dioxide in the deposited layer. In one aspect, the formed layer may contain about 5% to about 95% of titanium dioxide and with the balance being ruthenium dioxide. One advantage of this process, whether performed by sequential exposure to RuO₄ and another volatile oxide precursor or with vapors of both volatile precursors are mixed together, is it's utility for generating thin dense homogeneous and amorphous films characterize by a largely homogenous distribution of titanium oxides and ruthenium oxide that are interdispersed rather than merely a composite of TiO₂ and Ru0₂ nanoparticles, which is commonly formed using typical conventional processes. Such a structure can result through the oxidative displacement of isopropoxide moieties by RuO₄ diffusion in the intermediate sol, thereby avoiding the large volume decrease typically found in processes involving the thermal consolidation of a sol gel to form a dense metal oxide. The oxidizing properties of RuO₄ results in the degradation of isopropoxide to CO₂ and water, the later acting to promote further hydrolysis of titanium isopropoxide to generate a low carbon all inorganic mixed ruthenium-metal oxide structure containing a ruthenium titanium oxide. The final ratios of titanium to ruthenium in films derived by such process may be widely variable from a material containing relatively low levels of ruthenium (0.5-10% mole fraction of Ru) relative to total metal to an essentially 100% RuO₂ surface generated over only a thin layer of a titanium alkoxide initiation and adhesion layer at the substrate interface. While the example is given involving titanium and the titanium isoproxide precursor embodiments of the invention also extend to other listed examples of metal alkoxide precursors as well. Typically chamber pressures during the deposition process are maintained between 1 Torr and 1 atm (760 Torr) and more preferably between 2 Torr and about 200 Torr.

It has been found that the formation of layered structure and/or co-deposited layer of a metal oxide, such as titanium dioxide, and ruthenium dioxide can increase the adhesion strength and corrosion resistance of the formed conductive mixed metal oxide layer. Also, it is believed that the embodiments described herein have an advantage over conventional mixed metal oxides formed by sintering and annealing particles or partially condensed sol gel mixtures used as precursors to mixtures containing of ruthenium dioxide and titanium dioxide, since dense continuous and conductive films can be obtained at much lower temperatures over a variety of substrates (including polymers) with the significant shrinkage that normally accompanies alternative approaches.

It should be noted that in cases where it is desired to form a thin mixed ruthenium/titanium metal oxide layer involves a first step comprising either the patternwise or blanket coating of the substrate with a dilute solution of a titanium alkoxide solution in an alcohol solvent. Any of the above referenced process sequences can be implemented using, for example, a sol gel ink generated by combining about 1 gram of titanium isopropoxide, about 20 g or isopropanol and about 0.1 g H₂0. Depending on the printing method and substrate being patterned or coated, the concentrations of titanium isopropoxide and water may be increase or the solvent changed to achieve required wetting properties and evaporation rate. Subsequent exposure to Ru0₄ vapors is typically performed at or below 100° C. to generate the mixed ruthenium-titanium oxide exhibiting good conductivity and stability, without the necessity of high temperature anneal steps. However, if not precluded by the thermal stability of the substrate, higher temperature annealing can be useful to promote films exhibit crystalline character.

Interconnect Formation Process

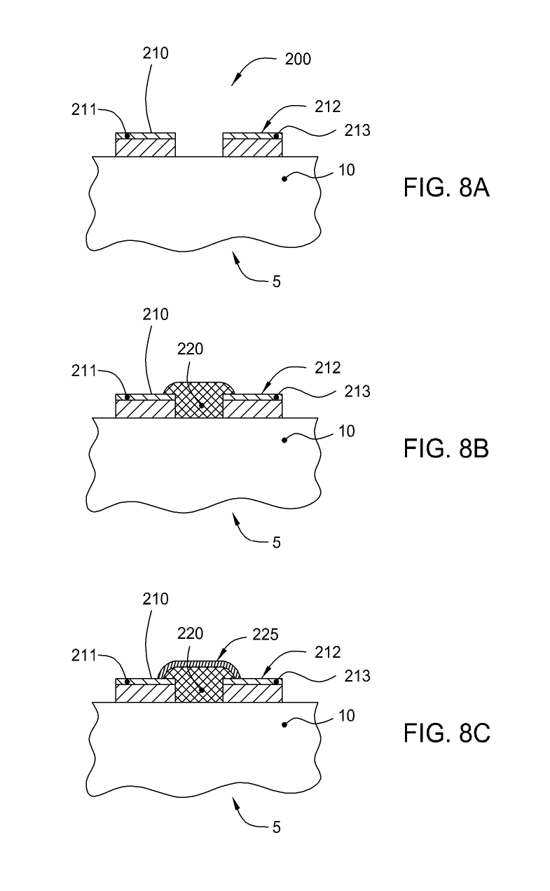

In one embodiment, an interconnect is formed between devices by use of a printing process and a ruthenium containing layer deposition process. FIG. 8A illustrates a cross-sectional view of a device structure 200 formed on a substrate 5 that has two devices 210 and 212 that each have an electrical contact 211 and 213, respectively. In the following process steps it is desirable to form an electrical interconnect between the various electrical contacts 221 and 213. The process generally includes the steps described below.

The first step, illustrated in FIG. 8B, is to deposit a silicon containing material 220 on the surface of the substrate. The silicon containing material 220 may be deposited by an inkjet printing or other process that allows the deposited material to be placed in desired positions on the surface of the substrate. For example, the dielectric material may be a photo-curable or thermally curable silicone based material with a general composition R₂₋ₓSiO_{1+0.5x}, where R=CH₃ and x is generally between 0.5<x<0.1. In one aspect a photo-curable silicone material is deposited across the surface of the substrate. Then the desired portion of the deposited silicone material is exposed to some light source to cause the material to cure in desired areas. In one embodiment, it is desirable to generate an insulating layer between adjacent devices (e.g., elements 210 and 212) formed on the substrate 5 surface using the photocurable silicon to create individual cells (see element 220 in FIG. 8B). The devices 210 and 212, in this case are typically formed as one sheet and are isolated from each other by a laser or mechanical scribing process to remove interconnecting layers and thus create individual cells. When these layers have been removed to exposed the underlying transparent glass substrate, such exposure may be performed by illumination through the glass substrate 5 from bottom/backside to generate a self aligned insulating layer in the exposed area, after which non-exposed regions can be removed using a suitable rinse solvent.

The substrate then is placed in a vacuum chamber and exposed to a ruthenium tetroxide containing gas at a temperature less than 180° C., preferably between 20° C. and 100° C. to selectively form a ruthenium containing layer 225 over the insulting silicone bridge to connect electrical contacts 211 and 213. The ruthenium tetroxide will preferentially form over the silicon containing material 220 and contact the exposed device layers (e.g., electrical contacts 211 and 213). Exemplary processes used to form ruthenium tetroxide and perform step 112 are discussed above in the section entitled “Ruthenium Process Chemistry And Enabling Hardware” and is described in the US Patent Publication No. 20060165892, which is incorporated by reference to the extent not inconsistent with the claimed aspects and description herein.

Thereafter, a bulk metal layer (not shown) can be formed over the ruthenium containing layer 225 by an electroless plating process to form the desired interconnect layer between individual photovoltaic cells or pixels.

While the foregoing is directed to embodiments of the present invention, other and further embodiments of the invention may be devised without departing from the basic scope thereof, and the scope thereof is determined by the claims that follow.

We claim:

1. A method of forming a conductive feature on the surface of a substrate, comprising:
depositing a coupling agent that contains a metal oxide precursor on a surface of a substrate; and
exposing the coupling agent and the surface of the substrate to a ruthenium tetroxide containing gas to form a ruthenium containing layer on the surface of the substrate.

2. The method of claim 1, further comprising depositing a conductive layer on the ruthenium containing layer using an electroless deposition process.

3. The method of claim 1, wherein the coupling agent is a oxidizing catalytic precursor containing a metal selected from a group consisting of ruthenium, osmium, cobalt, rhodium, iridium, nickel, palladium, platinum, copper, gold, and silver.

4. The method of claim 2, where in the conductive layer is formed from a conductive material selected from a group consisting of copper, cobalt, nickel, ruthenium, palladium, platinum, silver, and gold.

5. The method of claim 1, where in the surface of the substrate is formed from a material selected from a group consisting of a silicon dioxide, glass, silicon nitride, oxynitride, carbon-doped silicon oxides, amorphous silicon, doped amorphous silicon, zinc oxide, indium tin oxide, transition metals, and polymeric materials.

6. The method of claim 1, wherein the depositing the coupling agent comprises:
depositing the coupling agent to a desired region on the surface of a substrate; and
heating the substrate in a vacuum environment to a temperature below about 100° C.

7. A method of forming a conductive feature on the surface of a substrate, comprising:
depositing an organic containing material on a surface of a substrate;
exposing the organic material and the surface of the substrate to a ruthenium tetroxide containing gas, wherein the ruthenium tetroxide oxidizes the organic material to selectively deposit a ruthenium containing layer on the surface of the substrate; and
depositing a conductive layer on the ruthenium containing layer using an electroless deposition process.

8. The method of claim 7, where in the organic containing material is an organosilane material.

9. The method of claim 7, where in the conductive layer is formed from a conductive material selected from a group consisting of copper, cobalt, nickel, ruthenium, palladium, platinum, silver, and gold.

10. The method of claim 7, where in the surface of the substrate is formed from a material selected from a group consisting of a silicon dioxide, glass, silicon nitride, oxynitride, carbon-doped silicon oxides, amorphous silicon, doped amorphous silicon, zinc oxide, indium tin oxide, transition metals, and polymeric materials.

11. A method of forming a conductive feature on the surface of a substrate, comprising:
depositing a liquid coupling agent that contains a metal oxide precursor on a surface of a substrate;
reducing the metal oxide precursor using a reducing agent; and
depositing a conductive layer on the ruthenium containing layer using an electroless deposition process.

12. The method of claim 11, wherein the liquid coupling agent contains a high oxidation state metal selected from a group consisting of ruthenium, osmium, cobalt, rhodium, iridium, nickel, palladium, platinum, copper, gold, and silver.

13. The method of claim 11, where in the conductive layer is formed from a conductive material selected from a group consisting of copper, cobalt, nickel, ruthenium, palladium, platinum, silver, and gold.

14. The method of claim 11, where in the surface of the substrate is formed from a material selected from a group consisting of a silicon dioxide, glass, silicon nitride, oxynitride, carbon-doped silicon oxides, amorphous silicon, doped amorphous silicon, zinc oxide, indium tin oxide, transition metals, and polymeric materials.

15. The method of claim 11, wherein the depositing the coupling agent comprises:
depositing the coupling agent to a desired region on the surface of a substrate; and
heating the substrate in a vacuum environment to a temperature below about 100° C.

16. A method of selectively forming a layer on a surface of a substrate, comprising:
selectively applying a liquid coupling agent to a desired region on the surface of a substrate; and
forming a ruthenium containing layer within the desired region using a ruthenium tetroxide containing gas.

17. The method of claim 16, wherein the liquid coupling agent comprises a metal alkoxide.

18. The method of claim 16, wherein the metal in the metal alkoxide is selected from a group consisting of titanium, zirconium, hafnium, vanadium, niobium, tantalum, molybdenum, tungsten, silicon, germanium, tin, lead, aluminum, gallium, and indium.

19. The method of claim 16, wherein the selectively applying the liquid coupling agent comprises:
depositing the liquid coupling agent to a desired region on the surface of a substrate; and
heating the substrate in a vacuum environment to a temperature below about 100° C.

20. A layered metal oxide coating formed on a substrate, comprising:
a ruthenium containing coating formed by the decomposition of ruthenium tetroxide; and
a metal oxide coating formed by the decomposition of a vapor phase metal containing precursor.

21. The method of claim 20, wherein the vapor phase metal containing precursor is selected from a group consisting of titanium isopropoxide, titanium tetrachloride, tetrakis diethylaminotitanium, tetrakis dimethylaminotitanium, tin isopropoxide, tetramethyltin, tetrakis-dimethylaminotin, tungsten (V) ethoxide, tungsten (VI) ethoxide, zirconium isopropoxide, zirconium tetrakis-dimethylaminddimethylamide, hafnium tetrakis-ethylmethylamindethylmethylamide, hafnium tetrakis-dimethylamide, hafnium tetra-t-butoxide, hafnium tetraethoxide, vanadium tri-isopropoxide oxide, niobium (V) ethoxide, tantalum (V) ethoxide, and trimethylaluminum.

22. The method of claim 20, wherein the metal oxide contains an element selected from a group consisting of tungsten, molybdenum, vanadium, aluminum, hafnium, titanium, niobium, zirconium and tin.

23. A conductive coating formed on a substrate, comprising a mixed metal oxide coating deposited on a surface of the substrate by delivering a ruthenium tetroxide containing gas and a volatile metal oxide containing precursor to a surface of a substrate.

24. The method of claim 23, wherein the volatile metal oxide containing precursor is selected from a group consisting of titanium isopropoxide, titanium tetrachloride, tetrakis diethylaminotitanium, tetrakis dimethylaminotitanium, tin isopropoxide, tetramethyltin, tetrakis-dimethylaminotin, tungsten (V) ethoxide, tungsten (VI) ethoxide, zirconium isopropoxide, zirconium tetrakis-dimethylaminddimethylamide, hafnium tetrakis-ethylmethylamindethylmethylamide, hafnium tetrakis-dimethylamide, hafnium tetra-t-butoxide, hafnium tetraethoxide, vanadium tri-isopropoxide oxide, niobium (V) ethoxide, tantalum (V) ethoxide, and trimethylaluminum.

25. A method of forming a conductive feature on the surface of a substrate, comprising:
forming a dielectric layer between two discrete devices formed on a substrate surface by depositing a polymeric material on the surface of the substrate;
exposing the dielectric layer to a ruthenium tetroxide containing gas, wherein the ruthenium tetroxide oxidizes the surface of the dielectric layer to form a ruthenium containing layer; and
depositing a conductive layer on the ruthenium containing layer using an electroless deposition process.
